(19) United States
(12) Patent Application Publication
(10) Pub. No.: US 2015/0125989 A1
(43) Pub. Date: May 7, 2015

(54) METHOD FOR PREPARING LIGHT-ABSORBING LAYER FOR CIS- OR CIGS-BASED SOLAR CELLS, AND LIGHT-ABSORBING INK FOR CIS- OR CIGS-BASED SOLAR CELLS

(71) Applicant: GS CALTEX CORPORATION, Seoul (KR)

(72) Inventor: Yeokwon YOON, Daejeon (KR)

(21) Appl. No.: 14/509,434

(22) Filed: Oct. 8, 2014

Related U.S. Application Data
(63) Continuation-in-part of application No. PCT/KR2013/005698, filed on Jun. 27, 2013.

(30) Foreign Application Priority Data
Aug. 14, 2012 (KR) 10-2012-0088967

(51) Int. Cl. H01L 31/032; C09D 11/52; H01L 31/18

(52) U.S. Cl. CPC H01L 31/0322; H01L 31/1864; C09D 11/52
USPC 438/95; 252/519.21

(57) ABSTRACT

The present invention relates to a method for preparing a CIS- or CIGS-based light-absorbing layer which is to be included in thin-film solar cells. More particularly, the present invention relates to a method for preparing a CIS- or CIGS-based light-absorbing layer, which can ultimately improve the efficiency of solar cells, characterized by comprising the steps of: preparing a light-absorbing ink including a precursor of copper, indium, or gallium as an organic metal precursor, and a solvent, wherein a ligand in the organic metal precursor has a keto-enol tautomeric property; and coating a substrate with the light-absorbing ink and performing a heat treatment, thereby minimizing the remaining carbon impurities of the light-absorbing layer.

### TECHNICAL FIELD

The present invention relates to a method for preparing a CIS- or CIGS-based light-absorption layer for thin-film solar cells. More particularly, the present invention relates to a method for preparing a CIS- or CIGS-based light-absorption layer, which can minimize carbon impurities in the light-absorption layer, thereby ultimately improving conversion efficiency of solar cells.

### BACKGROUND ART

A solar cell is an essential device of a photovoltaic system that directly converts sunlight into electricity.

Generally, a solar cell is divided into a single-crystal silicon solar cell, a polycrystalline silicon solar cell, and a thin-film solar cell.

The single-crystal silicon solar cell has higher conversion efficiency than other kinds of solar cells and is suited for mass production through process improvement.

The polycrystalline silicon solar cell employs a low-grade silicon wafer as a source material. Although the polycrystalline silicon solar cell requires low fabrication costs, the polycrystalline silicon solar cell has lower conversion efficiency than the single-crystal silicon solar cell.

Since such single-crystal and polycrystalline silicon solar cells are prepared using a source material in a bulk state, these solar cells have problems of high material costs and a complicated fabrication process, thereby providing constraints on cost reduction.

To solve these problems, thin-film solar cells prepared through significant reduction in thickness of a substrate or through deposition of a thin-film solar cell on an inexpensive substrate such as a glass sheet have attracted attention in the art. Although the thin-film solar cell has lower conversion efficiency than the single-crystal and polycrystalline silicon solar cells, the thin-film solar cell has a possibility of reducing fabrication costs.

Recently, studies have been conducted to develop a thin-film solar cell using a compound semiconductor material such as CdTe, CuInSe₂ (CIS), or CuInGaSe₂ (CIGS), which has relatively high conversion efficiency. Particularly, many attempts have been made to further improve conversion efficiency of a thin-film solar cell using a CIS or CIGS compound semiconductor having relatively high conversion efficiency in a light-absorption layer.

Although the CIS or CIGS light-absorption layer is prepared by vacuum deposition, there are problems of complicated processing conditions, difficulty fabricating a large-area product, and large loss of a source material.

To solve these problems with vacuum deposition, a method for fabricating a non-vacuum CIS or CIGS light-absorption layer, which does not use a vacuum apparatus, is known in the art. Particularly, a printing method for fabricating a CIS or CIGS thin-film is known as the most available method in terms of processing speed, processing cost, and formation of large-area products.

Fabrication of the CIS or CIGS light-absorption layer by the printing method generally includes a method using ink or paste composed of a precursor and a method using ink or paste prepared by forming CIG or CIGS nanoparticles and distributing the particles.

As an exemplary method using a precursor, a method by Mitzi et al., disclosed in Advanced Materials, 2008, 20, 3657-3662, includes dissolving a binary compound, such as Cu₂S, In₂Se₃, or Ga₂Se, in hydrazine to form a precursor ink, depositing the precursor ink on a conductive substrate, and heat-treating the precursor ink under a nitrogen atmosphere, thereby fabricating a CIGS light-absorption layer. Further, a method by Min et al., disclosed in Journal of Crystal Growth, 2009, 311, 2621-2625, includes preparing paste by dissolving Cu(NO3)₂, In(NO3)3, Ga(NO3)3, and SeCl4 in an alcohol solvent and mixing an organic binder or the like therewith, depositing the paste on a conductive substrate, and then heat-treating the paste under a H₂/Ar atmosphere, thereby fabricating a CIGS thin-film.

As an exemplary method using nano-particles, a method by Kapur et al., disclosed in Thin Solid Films, 2003, 431-432, and 53-57, includes synthesizing and distributing CuInGa oxide nano-particles, depositing the nano-particles on a conductive substrate, and heat-treating the nano-particles under an H₂Se-gas atmosphere, thereby fabricating a CIGS light-absorption layer.

There among, the method using a precursor has a problem in that a large amount of carbon impurities remains when heat treatment is performed under a hydrogen or nitrogen atmosphere. Further, when a solvent such as hydrazine is used, remaining carbon impurities can be decreased. In this case, however, there is a drawback in that industrial applicability is restricted due to highly explosive properties of hydrazine.

The remaining carbon impurities act as a main element causing reduction in conversion efficiency of a solar cell. Thus, in order to solve the problems of the method for fabricating a light absorption layer by printing, there is a need for a preparation method capable of minimizing remaining carbon impurities while using a stable organic solvent.

### DISCLOSURE

### Technical Problem

The present invention has been conceived to solve such problems in the art and it is one aspect of the present invention to provide a method for preparing a CIS- or CIGS-based light-absorption layer for thin-film solar cells. More particularly, the present invention relates to a method for preparing a CIS- or CIGS-based light-absorption layer, which can minimize carbon impurities in the light-absorption layer, thereby ultimately improving solar cell conversion efficiency.

### Technical Solution

In accordance with one aspect of the present invention, a method for preparing a light-absorption layer for CIS- or CIGS-based solar cells includes: preparing a light-absorption ink including a precursor of copper, indium, or gallium as an organic metal precursor, and a solvent, wherein a ligand in the organic metal precursor exhibits keto-enol tautomerism; and coating the light-absorption ink onto a substrate, followed by heat treatment.

More specifically, the method includes: preparing a starting material containing a metal organic precursor by mixing a precursor of copper, indium or gallium; mixing the starting material with a solvent to prepare a light-absorption ink; mixing the light-absorption ink with a chelating agent to form a complex; coating the light-absorption ink onto a substrate to form a thin film, followed by heat treatment; and obtaining a CI thin-film or a CIG thin-film reduced, sulfurized, or selenized by heat treatment of the thin film under a hydrogen, sulfurization or selenization atmosphere, wherein the preparation of the light-absorption ink and the formation of the complex are sequentially or simultaneously carried out.

In accordance with another aspect of the present invention, there is provided a light-absorption ink for solar cells, which includes a precursor of copper, indium, or gallium as an organic metal precursor, and a solvent, wherein a ligand in the organic metal precursor exhibits keto-enol tautomerism.

### Advantageous Effects

Since the preparation method according to the present invention does not require a vacuum apparatus and minimizes consumption of a metal source material, the preparation method is very advantageous in terms of improvement of processing speed, processing cost, and formation of large area products.

In addition, the method according to the present invention can minimize carbon impurities in the light-absorption layer by providing a binder-free type light-absorption ink, thereby preventing deterioration in solar cell conversion efficiency.

### DESCRIPTION OF DRAWINGS

FIG. 1 shows a result of XRD(x-ray diffraction) pattern analysis for a CIS light-absorption thin-film prepared in Example 1.

FIG. 2 shows a TGA(thermogravimetric analyzer) result for Cu(acac)₂ used as a reactant in Example 1.

FIG. 3 shows a TGA analysis result for In(acac)₃ used as a reactant in Example 1.

FIG. 4 shows a TGA analysis result for acetyl acetone used as a solvent in Example 1.

FIG. 5 shows a TGA analysis result for ethanolamine used as a chelating agent in Example 1.

FIG. 6 shows a TGA analysis result for a CuIn light-absorption ink in Example 1.

### BEST MODE

Detailed features of other embodiments are included in the following description and the accompanying drawings.

The above and other aspects, features and advantages of the present invention will become apparent from the detailed description of the following embodiments in conjunction with the accompanying drawings. However, it should be understood that the present invention is not limited to the following embodiments and may be embodied in different ways, and that the embodiments are provided for complete disclosure and thorough understanding of the invention by those skilled in the art. The scope of the invention should be defined only by the accompanying claims and equivalents thereof.

Hereinafter, exemplary embodiments of the present invention will be described in detail.

In accordance with one aspect of the present invention, a method for preparing a light-absorption layer for CIS- or CIGS-based solar cells includes: preparing a light-absorption ink including a precursor of copper, indium, or gallium as an organic metal precursor, and a solvent, wherein a ligand in the organic metal precursor exhibits keto-enol tautomerism; and coating the light-absorption ink onto a substrate, followed by heat treatment.

More specifically, the method includes: preparing a starting material containing a metal organic precursor by mixing a precursor of copper, indium or gallium; mixing the starting material with a solvent to prepare a light-absorption ink; mixing the light-absorption ink with a chelating agent to form a complex; coating the light-absorption ink onto a substrate to form a thin film, followed by heat treatment; and obtaining a CI thin-film or a CIG thin-film reduced, sulfurized, or selenized by heat treatment of the thin film under a hydrogen, sulfurization or selenization atmosphere, wherein the preparation of the light-absorption ink and the formation of the complex are sequentially or simultaneously carried out. The steps of the method will now be described in more detail.

First, the starting material including the metal organic precursor is prepared by mixing the precursor of copper, indium or gallium. The precursor of copper, indium or gallium is a precursor that can generate metal ions. Although the precursor generally uses hydroxides, nitrates, sulfates, acetates, chlorides, or oxides of the metal ions or a mixture thereof, according to the present invention, the metal organic precursor is preferably a precursor in which a ligand in the organic metal precursor exhibits keto-enol tautomerism. More preferably, the ligand preferably comprises an acetylacetonate compound of the metal ions or a mixture thereof, which includes acetylacetonate. Thus, the precursors of copper, indium and gallium may be copper acetylacetonate (Cu(acac)₂), indium acetylacetonate (In(acac)₃), and gallium acetylacetonate (Ga(acac)₃), respectively. These compounds are selected for the purpose of using keto-enol tautomerism of the acetylacetonate included in the precursor and acetylacetone described below, which is a most-preferable solvent. This will be described in detail in the description with respect to a solvent.

The precursors of copper, indium and gallium may have a mole ratio of 1:0.5 to 2:0 to 2 in order to maximize light-conversion efficiency.

Next, the light-absorption ink is prepared by mixing the starting material with a solvent.

Here, the solvent preferably contains a ketone compound in order to allow the starting material to be dissolved in the solvent through simple heat treatment when the structure of acetylacetonate contained in the metal precursor becomes a keto form due to keto-enol tautomerism.

That is, as represented by Formula 1, keto-enol tautomerrism refers to a chemically equilibrium state between a keto form and an enol form, wherein the keto form and the enol form are rapidly interconverted to each other through the movement of a proton and the shifting of bonding electrons. Such specific isomers are called tautomers of each other.

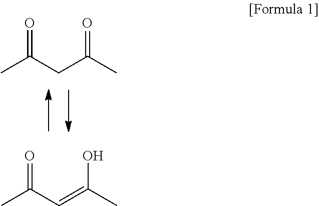

According to the present invention, the organic compound (for example, acetylacetonate) contained in the metal organic precursor is removed together with the solvent by heat treatment based on keto-enol tautomerism, thereby forming a light-absorption layer in which carbon impurities are minimized. An exemplary mechanism using copper acetylacetonate as the metal organic precursor can be represented by Formula 2.

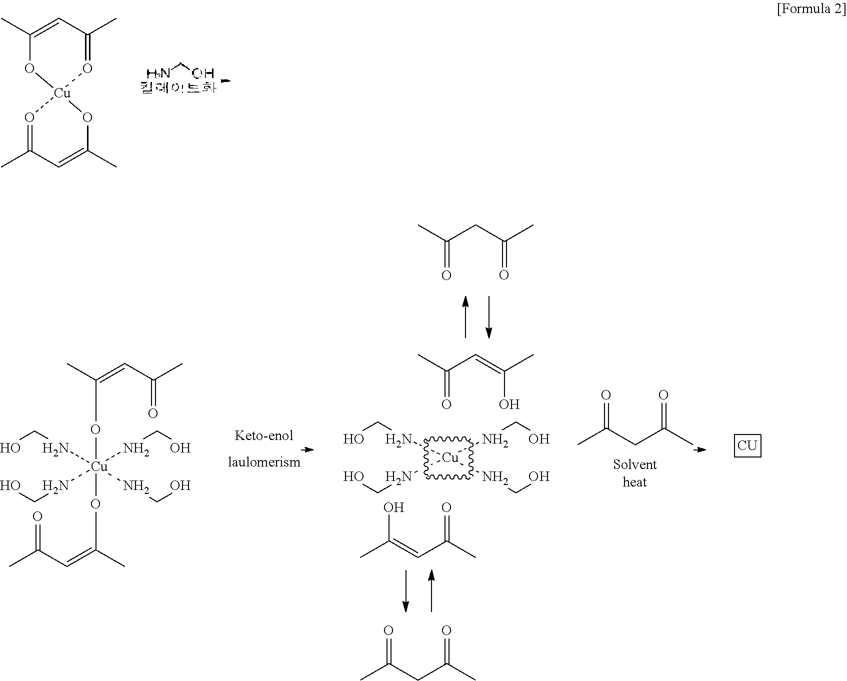

Accordingly, the solvent may include any ketone compound, and preferably includes at least one selected from among acetylacetone, acetone, methylacetylacetate, tertbutyl acetoacetate, and ethyl-2-methylacetoacetate.

Next, the complex is prepared by mixing the light-absorption ink with the chelating agent.

When mixed with the metal organic precursor contained in the starting material, the chelating agent is stabilized while forming the complex. In the present invention, the chelating agent may include any chelating agent which can form a complex with a molecular structure in the starting material. Preferably, the chelating agent includes amine or amine alcohol.

For example, when copper acetylacetonate is mixed with ethanolamine, a complex is formed as represented by Formula 3.

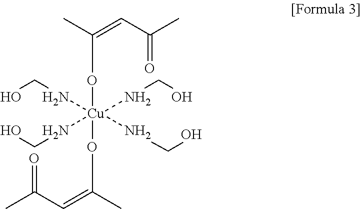

When such a complex is formed, solubility of the metal organic precursor increases with respect to solvent comprising the ketone compound in the ink, and thus the metal organic precursor is stabilized. Thus, keto-enol tautomerism is efficiently achieved by the ketone compound solvent. In addition, the formation of the complex provides sufficient viscosity such that a binder is not required, thereby forming a binder-free light-absorption ink.

Amine or amine alcohol may include at least one selected from among monoalkylamine (RNH₂; R being a C₁ to C₈ alkyl group), dialkylamine (R₁R₂NH: R₁ and R₂ being a C₁ to C₈ alkyl group), trialkylamine (R₁R₂, R₃N: R₁, R₂ and R₃ being a C₁ to C₈ alkyl group), diamine (R₁R₂N—R—NR₃R₄; R, R₁, R₂, R₃ and R₄ being H or a C₁ to C₈ alkyl group), monoalcoholamine (RHN₂OH: R being a C₁ to C₈ alkyl group), dialcoholamine [(R₁OH)(R₂OH)NH: R₁ and R₂ being a C₁ to C₈ alkyl group], trialcoholamine [(R₁OH)(R₂OH)(R₃OH)N: R₁, R₂ and R₃ being a C₁ to C₈ alkyl group].

On the other hand, the method according to the present invention may include preparing the light-absorption ink by mixing the solvent comprising the ketone compound with the starting material, and preparing the complex by mixing the prepared light-absorption ink with amine or amine alcohol used as a chelating agent, without being limited thereto. That is, after the starting material containing the metal organic precursor is prepared, the solvent comprising the ketone compound and the amine or amine alcohol may be simultaneously added thereto to form the complex. Alternatively, after the starting material containing the metal organic precursor is prepared, the prepared starting material may be first added to the amine or amine alcohol and then added to the solvent comprising the ketone compound.

In the claims, the expression “the preparation of the light-absorption ink and the formation of the complex are sequentially performed” means that after the light-absorption ink is prepared by mixing the solvent comprising the ketone compound with the starting material, the prepared light-absorption ink and the amine or amine alcohol which is a chelating agent are mixed to form the complex, and after the starting material containing the metal organic precursor is prepared, the starting material is first added to the amine or amine alcohol and then is added to the solvent comprising the ketone compound.

Next, the light-absorption ink, in which the complex is formed, is coated as a thin film on a substrate, followed by heat treatment.

Here, the substrate may be composed of any conductive material capable of resisting burning temperature, including, for example, ITO or FTO glass, Mo-coated glass, metal foil, a metal plate, a conductive polymer material, a conductive film-coated non-conductive substrate, or the like.

Thin-film coating may be performed by any typical methods including, for example, doctor-blade coating, screen-coating, spin-coating, spray-coating, slot-die coating, and the like. The coating thickness may ranges from 0.1 micrometers to 10 micrometers.

Heat treatment may be performed in a temperature ranging from 100° C. to 400° C. If heat treatment is performed at a temperature of less than 100° C., the solvent is not completely removed, and if heat treatment is performed at a temperature of higher than 400° C., a thin film can suffer from cracking. By heat treatment, a material, such as a solvent and a chelating agent, which can remain as a carbon source, is removed, thereby minimizing a remaining amount of carbon impurities.

Next, the thin film is heat treated under a hydrogen atmosphere, a sulfurization atmosphere, or a selenization gas atmosphere so as to from a CI or CIG thin-film through reduction, sulfurization, or selenization.

Such reduction, sulfurization or selenization may be performed by heat treatment under an atmosphere of H₂ or H₂S, S, H₂Se, Se, or a gas mixture of these gas and inert gas.

Heat treatment temperature may be determined depending upon the kind of substrate, preferably in the range from 400° C. to 600° C. Heat treatment at a temperature of less than 400° C. can cause insufficient crystallization and heat treatment at a temperature of higher than 600° C. can cause melting of a glass substrate.

As such, in the method according to the embodiment of the invention, stabilization can be achieved using a chelating agent by forming a complex of a metal organic precursor to be used in a light-absorption layer, a binder-free light-absorption layer can be prepared using a solvent having the same structure as the molecular structure in the complex, and the remaining carbon impurities in the light-absorption layer can be minimized, thereby improving solar cell efficiency.

In accordance with another aspect of the present invention, a light-absorption ink for solar cells includes a precursor of copper, indium, or gallium as an organic metal precursor, and a solvent, wherein a ligand in the organic metal precursor exhibits keto-enol tautomerism.

The light-absorption ink may form a complex with a metal organic precursor in terms of improved stability, solubility and viscosity of the light-absorption ink.

In the light-absorption ink, the precursor of copper, indium or gallium, the solvent, and the chelating agent have the same features as in the description of the preparation method.

After the light-absorption ink is coated onto the substrate to form a thin film and is then subjected to heat treatment, the obtained thin-film is subjected to heat treatment under a hydrogen, sulfurization, or selenization atmosphere so as to form a reduced, sulfurized, or selenized CI or CIG thin-film, thereby forming a light-absorption layer for CIS- or CIGS-based solar cells.

Hereinafter, the present invention will be described in more detail with reference to some examples. However, it should be understood that these examples are provided for illustration only and are not to be construed in any way as limiting the present invention.

### 1. PREPARATIVE EXAMPLES

### Example 1

### Preparation of CIS Light-Absorption Layer

After a starting material was prepared by mixing 200 mg (0.76 mmol) of Cu(acac)₂ with 314 mg (0.76 mmol) of In(acac)₃, 2 ml of acetylacetone and 2 ml of ethanolamine were mixed with the starting material to form a complex. Next, a light-absorption ink was prepared by stiffing the complex at 140° C. for 1 hour.

The prepared light-absorption ink was coated onto a Mo glass substrate by doctor-blade coating or spin-coating, and then heat-treated at 200° C. for 4 minutes under an air atmosphere, thereby obtaining a light-absorption layer-precursor thin-film.

The precursor thin-film was heat-treated at 550° C. for 15 minutes under a Se atmosphere, thereby forming a CIS light-absorption layer thin-film.

### Example 2

### Preparation of CIGS Light-Absorption Layer

A CIGS light-absorption layer thin-film was prepared in the same manner as in Example 1, except that a starting material was prepared by mixing 218 mg (0.53 mmol) of In(acac)₃ and 84 mg (0.23 mmol) of Ga(acac)₃, instead of 314 mg (0.76 mmol) of In(acac)₃.

### Comparative Example 1

### Preparation of CIGS Light-Absorption Layer Using CIG Precursor Paste

A CIG precursor paste was obtained by dissolving 1 g (5 mmol) of Cu(NO₃)₂.xH₂O, 0.4 g (1.6 mmol) of Ga(NO₃)₃.xH₂O, 1.12 g (3.7 mmol) of In(NO₃)₃.xH₂O in 100 ml of ethanol and stirring 40 ml of the ethanol solution in which 15 g of terpineol and 0.75 g of ethylcellulose were mixed.

The paste was coated onto an FTO glass substrate by spin coating, and then heat-treated at 450° C. for 40 minutes in air, thereby forming a light-absorption oxide thin-film.

The oxide thin-film was heat-treated at 500° C. for 40 minutes under an H₂S (1000 ppm)/Ar atmosphere, and then at 500° C. for 40 minutes under a Se/Ar atmosphere, thereby forming a CIS light-absorption layer thin-film.

### 2. EVALUATION

(1) XRD Analysis

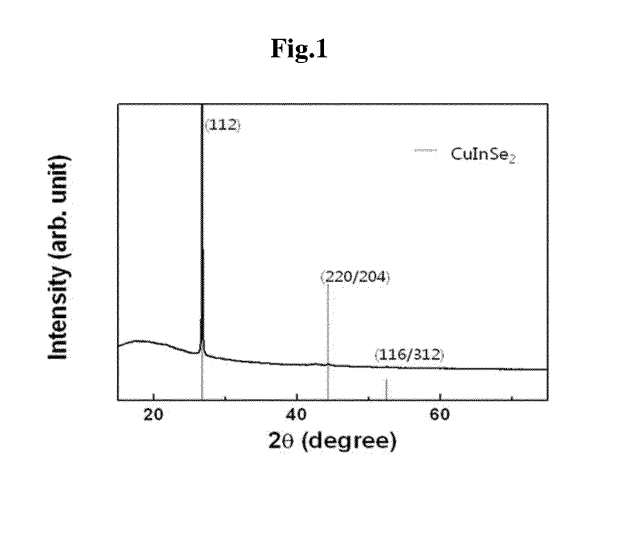

A result of XRD pattern analysis for the CIS light-absorption layer thin-film of Example 1 is shown in FIG. 1.

In FIG. 1, the XRD pattern analysis result showed that a CIS single-phase was successfully formed in the CIS thin-film of the inventive example.

(2) TGA Analysis

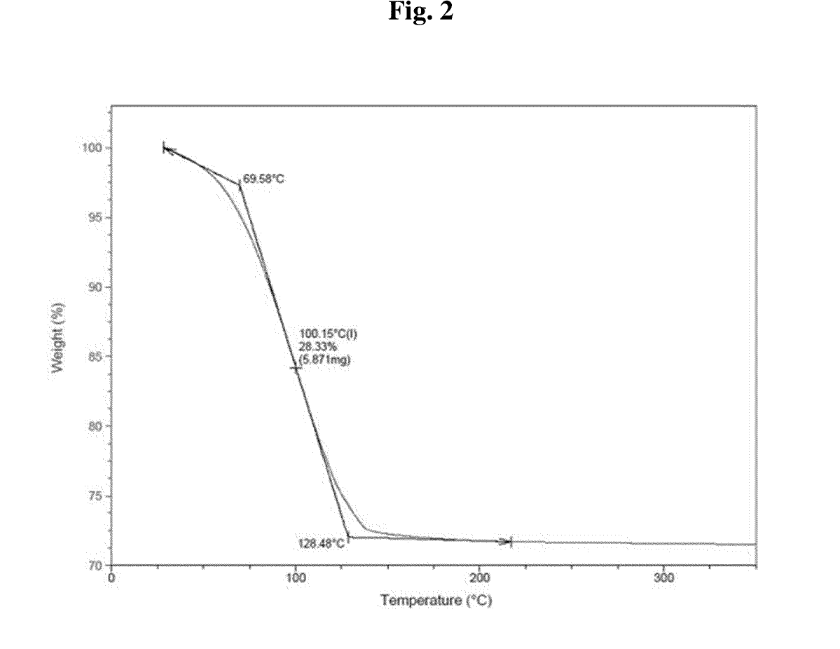

Results of TGA analysis for a reactant, a solvent, a chelating agent, and a CI light-absorption ink of Example 1 are shown in FIGS. 2 to 6.

FIG. 2 shows a TGA result for Cu(acac)₂ used as a reactant in Example 1.

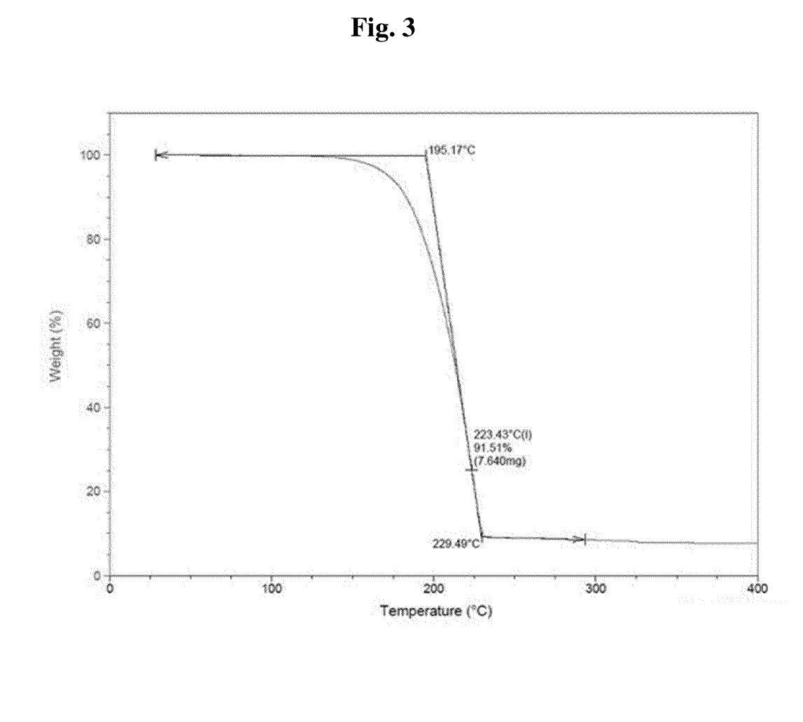

FIG. 3 shows a TGA result for In(acac)₃ used as a reactant in Example 1.

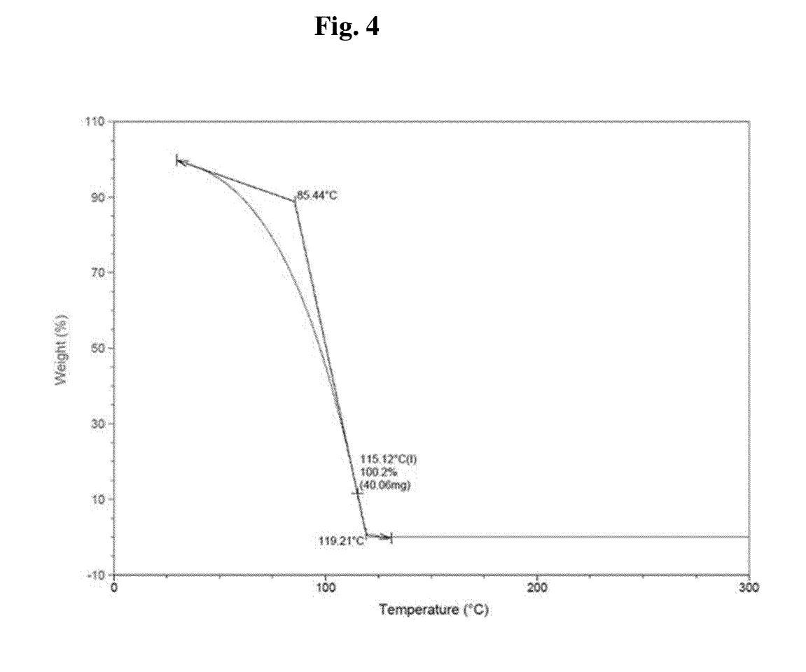

FIG. 4 shows a TGA result for acetyl acetone used as a solvent in Example 1.

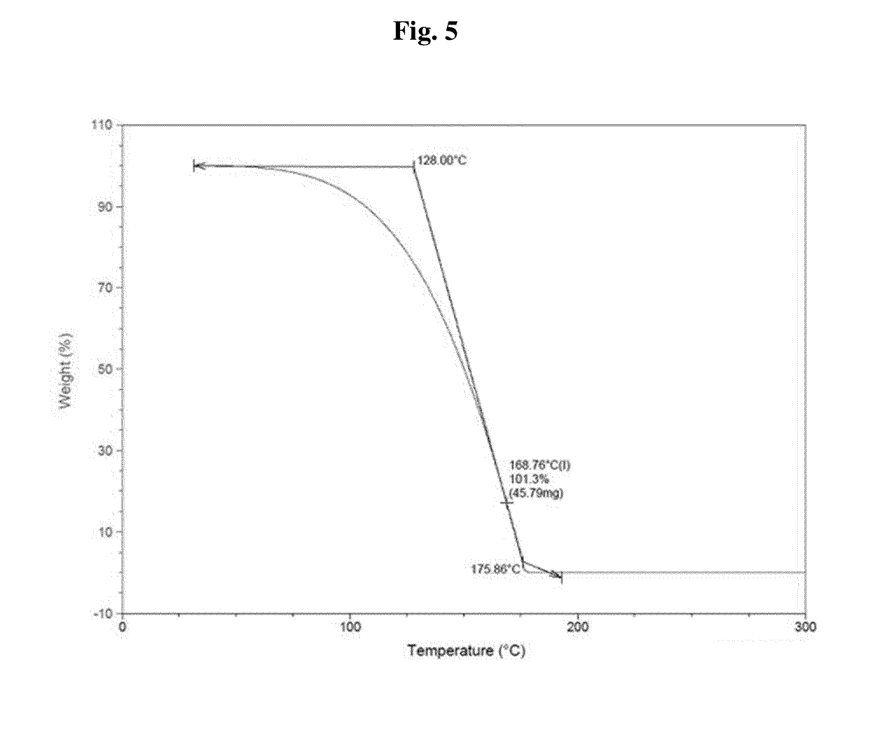

FIG. 5 shows a TGA result for ethanolamine used as a chelating agent in Example 1.

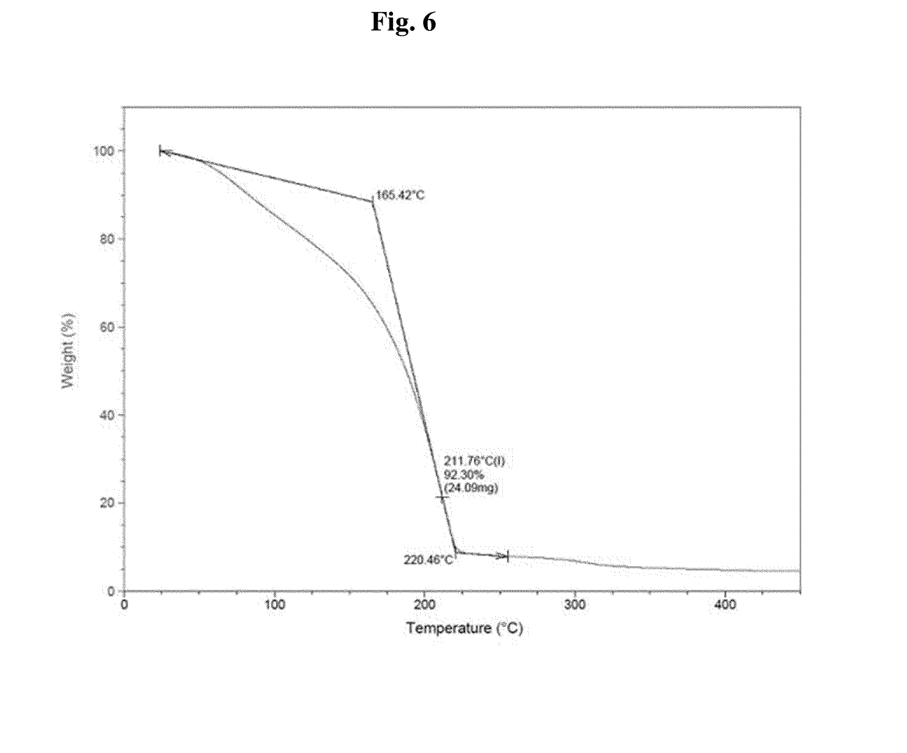

FIG. 6 shows a TGA result for a CuIn light-absorption ink in Example 1.

As shown in FIGS. 2 to 6, the TGA results showed that the light-absorption ink of Examples could remove a solvent and a chelating agent at a low temperature of 400° C. or less, preferably 300° C. or less, whereby materials possibly remaining as a carbon source could be removed, thereby minimizing remaining carbon impurities.

As can be seen these results, the method according to the present invention can easily remove a solvent and a chelating agent at a relatively low temperature in preparation of a light-absorption layer. In addition, as compared with a typical method like Comparative Example in which the light-absorption layer is prepared using a metal organic precursor paste using a binder, the method according to the present invention can minimize carbon impurities in the light-absorption layer and thus improve conversion efficiency of a solar cell.

Although some embodiments have been described above, it should be understood that these embodiments are provided for illustration only, and that various modifications, changes, alterations, and equivalent embodiments can be made by those skilled in the art without departing from the spirit and scope of the invention. Therefore, the scope of the invention should be limited only by the accompanying claims and equivalents thereof.

1. A method for preparing a light-absorption layer for CIS- or CIGS-based solar cells, comprising:
preparing a light-absorption ink including a precursor of copper, indium, or gallium as an organic metal precursor, and a solvent, wherein a ligand in the organic metal precursor exhibits keto-enol tautomerism; and
coating the light-absorption ink onto a substrate, followed by heat treatment.

2. The method according to claim 1, wherein the precursor of copper, indium or gallium comprises an acetylacetonate compound, the solvent comprises a ketone compound, and an acetylacetonate structure in the precursor is transformed into a keto form by keto-enol tautomerism to be removed together with the solvent upon heat treatment.

3. The method according to claim 1, further comprising: forming a complex with the metal organic precursor using a chelating agent.

4. The method according to claim 1, wherein the precursors of copper, indium and gallium comprise copper acetylacetonate, indium acetylacetonate, and gallium acetylacetonate, respectively.

5. The method according to claim 1, wherein the precursors of copper, indium and gallium have a mole ratio of 1:0.5 to 2:0 to 2.

6. The method according to claim 3, wherein the chelating agent comprises at least one amine or amine alcohol selected from among monoalkylamine (RNH₂; R being a C₁ to C₈ alkyl group), dialkylamine (R₁R₂NH: R₁ and R₂ being a C₁ to C₈ alkyl group), trialkylamine (R₁R₂, R₃N: R₁, R₂ and R₃ being a C₁ to C₈ alkyl group), diamine (R₁R₂N—R—NR₃R₄; R, R₁, R₂, R₃ and R₄ being H or a C₁ to C₈ alkyl group), monoalcoholamine (RHN₂OH: R being a C₁ to C₈ alkyl group), dialcoholamine [(R₁OH)(R₂OH)NH: R₁ and R₂ being a C₁ to C₈ alkyl group], trialcoholamine [(R₁OH)(R₂OH)(R₃OH)N: R₁, R₂ and R₃ being a C₁ to C₈ alkyl group].

7. The method according to claim 2, wherein the ketone compound comprises at least one selected from among acetylacetone, acetone, methylacetylacetate, tertbutyl acetoacetate, and ethyl-2-methylacetoacetate.

8. The method according to claim 1, wherein heat treatment is performed at a temperature ranging from 100° C. to 400° C.

9. The method according to claim 1,
the method comprising;
obtaining a CI thin-film or a CIG thin-film reduced, sulfurized, or selenized by heat treatment of the thin film under a hydrogen, sulfurization or selenization atmosphere heat treatment of the thin film under a hydrogen, wherein sulfurization or selenization atmosphere is performed at a temperature ranging from 400° C. to 600° C., following coating the light-absorption ink onto a substrate and heat treatment.

10. A light-absorption ink for CIS-based or CIGS-based solar cells, comprising:
a precursor of copper, indium, or gallium as an organic metal precursor; and
a solvent,
wherein a ligand in the organic metal precursor exhibits keto-enol tautomerism.

11. The light-absorption ink according to claim 10, wherein a complex with the metal organic precursor is formed using a chelating agent.

12. The light-absorption ink according to claim 10, wherein the precursors of copper, indium and gallium comprise copper acetylacetonate, indium acetylacetonate, and gallium acetylacetonate, respectively, and the solvent comprises a ketone compound.

13. The light-absorption ink according to claim 10, wherein the precursors of copper, indium and gallium have a mole ratio of 1:0.5 to 2:0 to 2.

14. The light-absorption ink according to claim 12, wherein the ketone compound comprises at least one selected from among acetylacetone, acetone, methylacetylacetate, tertbutyl acetoacetate, and ethyl-2-methylacetoacetate.

15. The light-absorption ink according to claim 11, wherein the chelating agent comprises at least one amine or amine alcohol selected from among monoalkylamine (RNH₂; R being a C₁ to C₈ alkyl group), dialkylamine (R₁R₂NH: R₁ and R₂ being a C₁ to C₈ alkyl group), trialkylamine (R₁R₂, R₃N: R₁, R₂ and R₃ being a C₁ to C₈ alkyl group), diamine (R₁R₂N—R—NR₃R₄; R, R₁, R₂, R₃ and R₄ being H or a C₁ to C₈ alkyl group), monoalcoholamine (RHN₂OH: R being a C₁ to C₈ alkyl group), dialcoholamine [(R₁OH)(R₂OH)NH: R₁ and R₂ being a C₁ to C₈ alkyl group], trialcoholamine [(R₁OH)(R₂OH)(R₃OH)N: R₁, R₂ and R₃ being a C₁ to C₈ alkyl group].

16-21. (canceled)

22. The method according to claim 2, further comprising: forming a complex with the metal organic precursor using a chelating agent.

23. The method according to claim 2, wherein the precursors of copper, indium and gallium comprise copper acetylacetonate, indium acetylacetonate, and gallium acetylacetonate, respectively.

24. The method according to claim 2, wherein the precursors of copper, indium and gallium have a mole ratio of 1:0.5 to 2:0 to 2.

25. The method according to claim 22, wherein the chelating agent comprises at least one amine or amine alcohol selected from among monoalkylamine (RNH₂; R being a C₁ to C₈ alkyl group), dialkylamine (R₁R₂NH: R₁ and R₂ being a C₁ to C₈ alkyl group), trialkylamine (R₁R₂, R₃N: R₁, R₂ and R₃ being a C₁ to C₈ alkyl group), diamine (R₁R₂N—R—NR₃R₄; R, R₁, R₂, R₃ and R₄ being H or a C₁ to C₈ alkyl group), monoalcoholamine (RHN₂OH: R being a C₁ to C₈ alkyl group), dialcoholamine [(R₁OH)(R₂OH)NH: R₁ and R₂ being a C₁ to C₈ alkyl group], trialcoholamine [(R₁OH)(R₂OH)(R₃OH)N: R₁, R₂ and R₃ being a C₁ to C₈ alkyl group].

26. The method according to claim 2, wherein heat treatment is performed at a temperature from 100° C. to 400° C.
